(19) United States
(12) Patent Application Publication
(10) Pub. No.: US 2010/0295819 A1
(43) Pub. Date: Nov. 25, 2010

(54) CONNECTION STRUCTURE BETWEEN ELECTRODES AND TOUCH PANEL

(75) Inventors: Masao OZEKI, Arakawa-ku (JP); Shinju OTANI, Arakawa-ku (JP); Shuji NISHIDA, Arakawa-ku (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: OPTREX Corporation, Arakawa-ku (JP)

(21) Appl. No.: 12/782,221

(22) Filed: May 18, 2010

(30) Foreign Application Priority Data
May 19, 2009 (JP) 2009-121354

(51) Int. Cl. G06F 3/045; H05K 1/00

(52) U.S. Cl. 345/174; 174/250; 174/258; 178/18.06

(57) ABSTRACT

A connection structure between electrodes includes a center electrode disposed as a transparent electrode on a transparent substrate; paired side electrodes disposed as transparent electrodes on the transparent substrate so as to place the center electrode therebetween; a bridge wire serving as a wire to connect between the paired side electrodes; and an electrically insulating film disposed between the center electrode and the bridge wire; wherein the bridge wire comprises a metal material; the electrically insulating film is disposed so as to be out of contact with the side electrodes at least within a certain range; and the bridge wire is disposed so as to be brought into direct contact with the transparent substrate in a gap region, the gap region being formed by disposing the electrically insulating film so as to bring out of contact with the side electrodes.

### BACKGROUND OF THE INVENTION

1. Field of the Invention

The present invention relates to a connection structure between electrodes for electrode connection on a substrate, and to a touch panel.

2. Discussion of Background

For example, there is a case where a first electrode pattern and a second electrode pattern are disposed to cross each other on a glass substrate forming a touch panel. With respect to the connection structure between electrodes in such a case, e.g. JP-A-2008-310550 discloses a capacitive input device, which includes a first translucent electrode pattern and a second translucent electrode pattern disposed on one side of a translucent substrate, wherein the second translucent electrode pattern, which is interrupted at portions where both patterns cross each other, is electrically connected by a relay electrode disposed on a top layer of an interlayer insulating film at each of the crossing portions (see paragraphs 0025 to 0027 and FIG. 8 of this reference).

Further, e.g. JP-A-2008-310551 discloses a capacitive input device, which includes a first translucent electrode pattern and a second translucent electrode pattern, wherein each of the first translucent electrode pattern and a second translucent electrode pattern is formed of a multilayer film having at least three laminated layers of at least a first translucent conductive film, a translucent insulating film and a second translucent conductive film. In the capacitive input device disclosed in this reference (see paragraphs 0009 to 0012 and FIG. 4), the second translucent electrode pattern, which is interrupted at portions where the second translucent electrode pattern crosses the first translucent electrode pattern, is electrically connected by a relay electrode disposed on a top layer of the interlayer insulating film at each of the crossing portions, and each of the first translucent conductive film and the second translucent conductive film has a conductive film for short-circuit entirely or substantially entirely disposed on an outer periphery in a continuous form for electrical connection. This reference also discloses an example where the relay electrode and the conductive film for short-circuit are formed of the same material.

### SUMMARY OF THE INVENTION

For example, JP-A-2008-310550 discloses that the insulating film is formed of a photosensitive resin, and that each of the translucent electrode patterns or the relay electrode is made of ITO (Indium Tin Oxide). However, the inventors have found that the use of a resin for formation of the interlayer insulating film could cause a problem of poor adhesion performance for the ITO (Indium Tin Oxide) or the like, depending on the property of the used resin material, when each of the translucent electrode patterns or the relay electrode is formed of ITO (Indium Tin Oxide).

FIGS. 10(a) to (d) are schematic views showing a connection structure between electrodes in a case where a first electrode pattern 92 and a second electrode pattern 93 are disposed so as to cross each other on a substrate 91 forming a touch panel or the like. In these views, FIG. 10(a) is a plan view showing an arrangement example of electrodes before connection. FIG. 10(b) is a cross-sectional view taken along line A-A′ in the arrangement example of the electrodes shown in FIG. 10(a). FIG. 10(c) is a plan view showing an example of the connection structure where electrode connection is made. FIG. 10(d) is a cross-sectional view taken along line A-A′ in the example of the connection structure shown in FIG. 10(c).

In the case shown in FIGS. 10(a) to (d), when the electrode pattern 92 and the electrode pattern 93 are disposed on the substrate 91, one of the electrode patterns 92 is disposed, being divided into an electrode 92a and an electrode 92b (see FIGS. 10(a) and (b)). The electrode 92a and the electrode 92b is connected by a bridge wire 95, which is disposed so as to bridge an insulating film 94 disposed to cover at least a crossing region (a hatched area 97 in FIG. 10(a)) on the other electrode pattern 93 (see FIGS. 10(c) and (d)).

The inventors have found that such a connection structure could cause a problem in that when the electrode patterns 92 and 93, and the bridge wire 95 are made of ITO, and when the insulating film 94 is formed of a resin, the resin insulating film 94 peels at portions 98 and 99 riding on the electrode 92a and the electrode 92b since the resin insulating film 94 has a poor adhesion to ITO, with the result that the bridge wire 95 disposed as a top layer on the insulating film is lifted to cause a connection failure.

In consideration of the above-mentioned problem, it is an object of the present invention to provide a connection structure between electrodes, which is capable of firmly connecting two transparent electrodes disposed on a transparent substrate with another transparent electrode being placed therebetween, and a touch panel employing the connection structure between electrodes.

The present invention provides a connection structure between electrodes, which includes a center electrode (such as a transparent electrode formed of an electrode element 201_{c}, an electrode element 201_{d} and a connection wire 202 shown in FIG. 2, an electrode 220 shown in FIG. 4, or an electrode 2B shown in FIG. 5) disposed as a transparent electrode on a transparent substrate (such as a transparent substrate 1 shown in the accompanying drawings); paired side electrodes (such as electrode elements 201ₐ, and 201_{b} shown in FIG. 2, electrodes 210 shown in FIG. 4, or electrodes 2A shown in FIG. 5) disposed as transparent electrodes on the transparent substrate so as to place the center electrode therebetween; a bridge wire (such as a bridge wire 4 shown in the accompanying drawings) serving as a wire to connect between the paired side electrodes; and an electrically insulating film (such as an electrically insulating film 3 shown in the accompanying drawings) disposed between the center electrode and the bridge wire; wherein the bridge wire comprises a metal material; the electrically insulating film is disposed so as to be out of contact with the side electrode at least within a certain range; and the bridge wire is disposed so as to be brought into direct contact with the transparent substrate in a gap region, the gap region being formed by disposing the electrically insulating film so as to be out of contact with the side electrodes.

The electrically insulating film may be disposed so as to be out of contact with the side electrodes at least within a region where the bridge wire is disposed.

The present invention also provides a connection structure between electrodes, which includes a center electrode disposed as a transparent electrode on a transparent substrate; paired side electrodes disposed as transparent electrodes on the transparent substrate so as to place the center electrode therebetween; a bridge wire serving as a wire to connect between the paired side electrodes; and an electrically insulating film disposed between the center electrode and the bridge wire; wherein the bridge wire comprises a metal material; and the bridge wire connecting between the paired side electrodes disposed so as to place the center electrode therebetween has a region to be brought into direct contact with the transparent substrate on both sides of the center electrode.

The present invention also provides a connection structure between electrodes, which includes a center electrode disposed as a transparent electrode on a transparent substrate; paired side electrodes disposed as transparent electrodes on the transparent substrate so as to place of the center electrode therebetween; an electrically insulating film disposed so as to bridge a portion of the center electrode; and a bridge wire bridging the electrically insulating film to serve as a wire to connect between the paired side electrodes; wherein the bridge wire is formed of a metal material; and the electrically insulating film disposed so as to bridge the portion of the center electrode has both edges extending so as to be out of contact the paired side electrodes and forming a gap region so as to prevent both edges from being brought into contact with the side electrodes, and the bridge wire is brought into direct contact with the transparent substrate in the gap region.

It is preferred that the electrically insulating film be formed of a resin material.

The present invention also provides a touch panel including a center electrode disposed as a transparent electrode on a transparent substrate; and paired side electrodes disposed on the transparent substrate so as to place the center electrode therebetween, the paired side electrodes being connected together without being brought into electrical contact with the center electrode such that electrode arrays cross on a single side of the transparent substrate; the touch panel further including: a bridge wire serving as a wire to connect between the paired side electrodes; and an electrically insulating film disposed between the center electrode and the bridge wire; wherein the bridge wire comprises a metal material; the electrically insulating film is disposed so as to be out of contact with the side electrode at least within a certain range; and the bridge wire is disposed so as to be brought into direct contact with the transparent substrate in a gap region, the gap region being formed by disposing the electrically insulating film so as to be out of contact with the side electrode.

The present invention also provides a touch panel including a center electrode disposed as a transparent electrode on a transparent substrate; and paired side electrodes disposed as transparent electrodes on the transparent substrate so as to place the center electrode therebetween, the paired side electrodes being connected together without being brought into electrical contact with the center electrode such that electrode arrays cross on a single side of the transparent substrate; the touch panel further including a bridge wire serving as a wire to connect between the paired side electrodes; and an electrically insulating film disposed between the center electrode and the bridge wire; wherein the bridge wire comprises a metal material; and the bridge wire connecting between the paired side electrodes disposed so as to place the center electrode therebetween has a region to be brought into direct contact with the transparent substrate on both sides of the center electrode.

The present invention also provides a touch panel including a center electrode disposed as a transparent electrode on a transparent substrate; and paired side electrodes disposed as transparent electrodes on the transparent substrate so as to place the center electrode therebetween, the paired side electrodes being connected together without being brought into electrical contact with the center electrode such that electrode arrays cross on a single side of the transparent substrate; the touch panel further including an electrically insulating film disposed so as to bridge a portion of the center electrode; and a bridge wire bridging the electrically insulating film to serve as a wire to connect between the paired side electrodes; wherein the bridge wire comprises a metal material; and the electrically insulating film disposed so as to bridge the portion of the center electrode has both edges extending so as to be out of contact the paired side electrodes and forming a gap region to prevent both edges from being brought into contact with the side electrodes, and the bridge wire is brought into direct contact with the transparent substrate in the gap region.

In accordance with the present invention, it is possible to firmly connect two transparent electrodes disposed on a transparent substrate with another transparent electrode being placed therebetween.

### BRIEF DESCRIPTION OF THE DRAWINGS

FIGS. 1(a) and (b) are schematic views showing a typical example of a touch panel including a connection structure between electrodes according to the present invention;

FIG. 2 is a schematic view showing an arrangement example of a transparent electrode pattern;

FIG. 3 is another schematic view showing the arrangement example of the transparent electrode pattern;

FIG. 4 is a schematic view showing a state where a transparent electrode pattern, an insulating film and a bridge wire are laminated;

FIG. 5 is a schematic view showing another arrangement example of the transparent electrode pattern, the insulating film and the bridge wire;

FIG. 6 is a schematic view showing an arrangement example of the touch panel where an insulating film is disposed;

FIG. 7 is a schematic view showing the arrangement example of the transparent pattern in Example 1;

FIG. 8 is a schematic cross-sectional view showing another structure example of the touch panel;

FIG. 9 is a schematic cross-sectional view showing an typical example of the display device having a function of serving as a capacitive touch panel; and

FIGS. 10(a) to (d) are schematic views showing a typical example of a connection structure between electrodes.

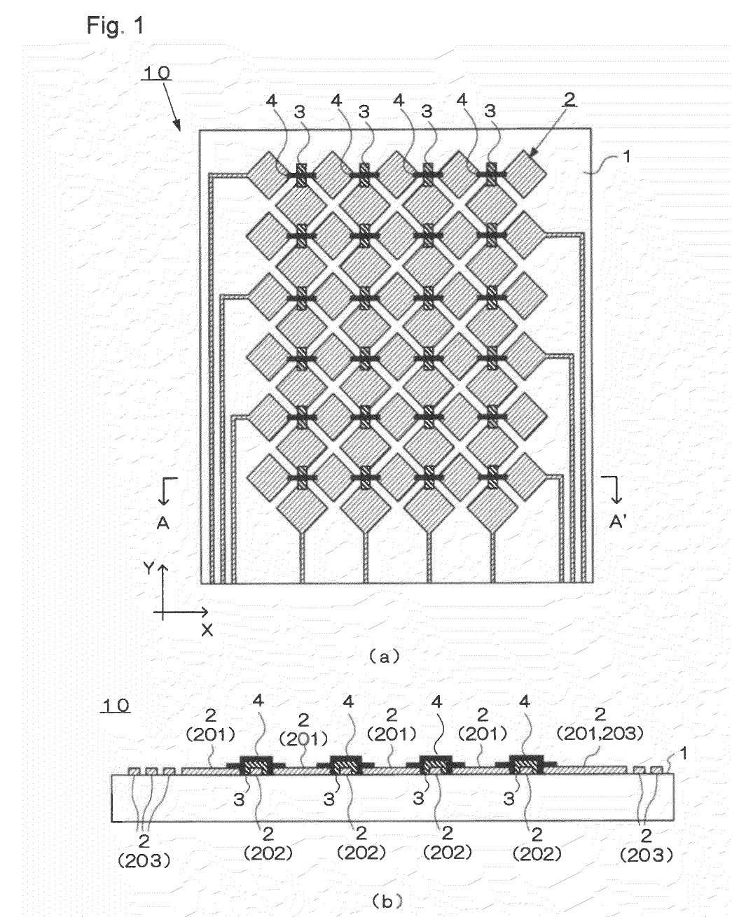

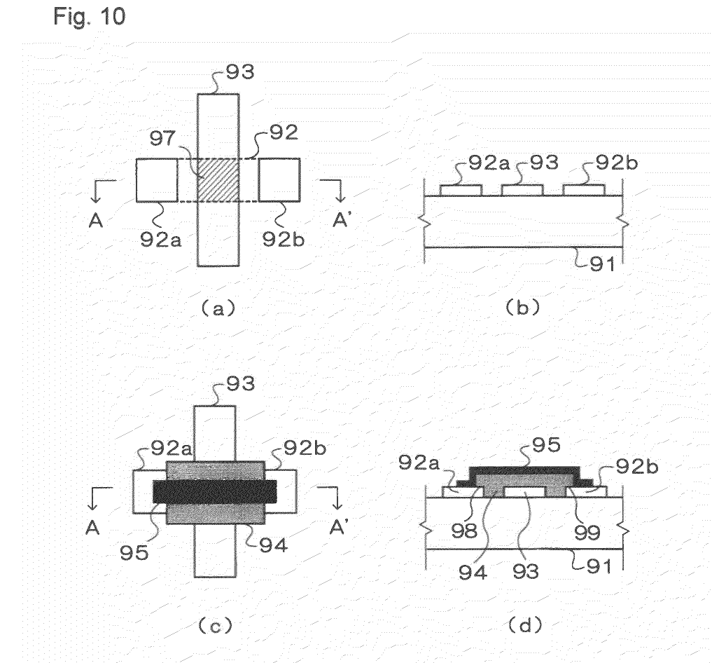

Now, embodiments of the present invention will be described in reference to accompanying drawings. FIGS. 1(a) and (b) are schematic views showing a structure example of the touch panel according to an embodiment of the present invention. The touch panel 10 shown in FIGS. 1(a) and (b) is a touch panel including a connection structure between electrodes according to the present invention. FIG. 1(a) is a plan view of the touch panel 10. FIG. 1(b) is a cross-sectional view of the touch panel 10 taken along line A-A′ of FIG. 1(a). Please note that the plan view shown in FIG. 1(a) is a plan view seen from a rear side of the touch panel 10, and that the rear side of the touch panel is positioned in an upper portion in the cross-sectional view shown in FIG. 10(b).

The touch panel shown in FIGS. 1(a) and (b) has a plurality of electrode arrays disposed on one side of a transparent substrate 1, such as a glass substrate, to extend along two axis directions of an X-axis and a Y-axis crossing the X-axis, respectively, such that these electrode arrays interpose an electrically insulating film therebetween at the crossing portions to be prevented from being brought into electrical contact. Explanation will be made with the electrodes forming the electrode arrays extending along the X-axis direction being called side electrodes, and the electrodes forming the electrode arrays extending along the Y-axis direction being called center electrodes. Please note that the electrodes forming the electrode arrays extending along the X-axis direction may be called center electrodes, and the electrodes forming the electrode arrays extending along the Y-axis direction may be called side electrodes, depending on the direction to see the touch panel. In order to detect where a touch is made, the side electrodes and the center electrodes, which are disposed along the respective axis directions, need to be independent from each other. In order to meet this requirement, in this embodiment, electrode array patterns forming the side electrodes and electrodes array patterns forming the center electrodes (plural electrode array patterns extending along the respective axis directions), which place the side and center electrodes in a matrix pattern, are disposed as a single layer transparent electrode pattern 2 on one side of a transparent substrate. Further, the transparent electrode pattern 2, which is interrupted so as to prevent the electrodes arrayed along one of the two directions from being brought into contact with the electrodes arrayed along the other direction in regions where the electrodes arrayed along the one direction cross the electrodes arrayed along the other direction, is disposed on the one side of the transparent substrate. Furthermore, individual bridge wires 4 are disposed so as to connect between the respective interpreted portions of the transparent electrode pattern 2. An insulating film 3, which is formed of an insulating substance, is disposed between the transparent electrode pattern 2 and each of the bridge wires 4 in each region (each crossing region) where the transparent electrode pattern 2 and a bridge wire 4 overlap. In this way, the side electrodes disposed along the X-axis direction and the center electrodes disposed along the Y-axis direction are disposed in a matrix pattern on the one side of the transparent substrate 1. When reference is made to the side electrodes or the center electrodes in the following explanation, it may be understood in some cases that the respective electrodes forming the side electrodes or the center electrodes are electrically connected through the respective interposed bridge wires 4 or the like along the axis direction for the arrayed electrodes to be aligned.

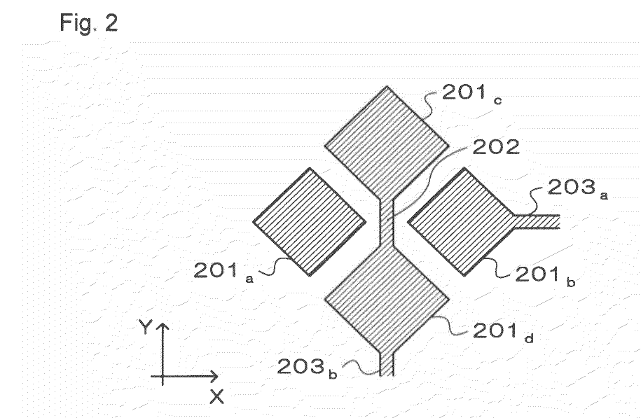

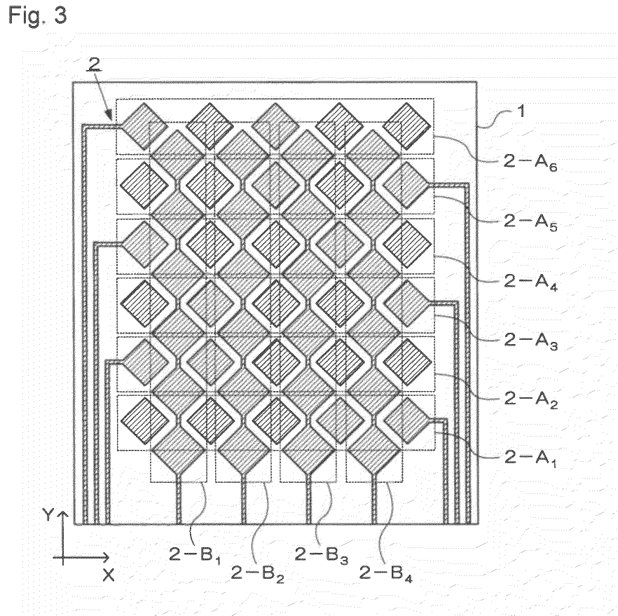

FIGS. 2 and 3 show an example of the transparent electrode pattern 2. When two crossing axes are formed of an X-axis direction and a Y-axis direction, the transparent electrode pattern 2 shown in FIGS. 1(a) and (b) is at least formed of electrode sets containing more than one electrode element 201 (such as electrode elements 201ₐ and 201_{b}) arrayed along the X-axis direction and more than one electrode element 201 (such as electrode elements 201_{c} and 201_{d}) arrayed along the Y-axis direction, and a connection wire 202 connecting only the electrode elements disposed along one of the axis directions in the electrode sets disposed in such a positional relationship to cross along the X-axis direction and the Y-axis direction (the electrode elements 201ₐ and 201 _{b} and the electrode elements 201_{c} and 201_{d} in the case shown in FIG. 2) as locally shown in FIG. 2. For example, the electrode elements 201ₐ and 201 _{b} shown in FIG. 2 correspond to elements forming an electrode array pattern 2-A₁ shown in FIG. 3. Further, for example, the electrode elements 201_{c} and 201_{d} shown in FIG. 2 correspond to elements forming an electrode array pattern 2-B₁ shown in FIG. 3. In FIG. 2, circuitous wires 203, such as circuitous wires 203ₐ and 203_{b}, to the respective electrode sets are also shown. It is sufficient that each circuitous wire 203 is connected to one of the electrode elements 201 forming each electrode array pattern.

An electrode array pattern may be formed so as to have a continuous electrode without separating the connection wires 202 from the electrode elements 201. For example, in the case shown in FIG. 2, the electrode element 201_{c}, the electrode element 201_{d} and the connection wire 202 may be formed as a single transparent electrode without being formed as separate elements. In this case, it may be understood that there are three independent transparent electrodes formed of a single first transparent electrode (a transparent electrode formed of the electrode element 201_{c}, the electrode element 201_{d} and the connection wire 202 in this embodiment) and two second transparent electrodes (the electrode element 201ₐ and the electrode element 201_{b} in this embodiment) spaced so as to place the first transparent electrode therebetween in the case shown in FIG. 2.

In this embodiment, each series of electrode elements 201 aligned along each of the axis-directions is grasped as a single electrode array pattern as shown in FIG. 3, irrespectively of whether adjacent electrode elements 201 are connected by a connection wire 202 or not. This is because adjacent electrode elements are finally connected by a bridge wire 4 (see FIGS. 1(a) and (b)) even if the adjacent electrode elements are not connected by the bridge wire 4 when the transparent electrode pattern 2 is disposed. In the case shown in FIG. 3, it may be understood that ten electrode array patterns 2-A₁ to 2-A₆ and 2-B₁ to 2-B₄ are disposed.

FIG. 3 shows a case where six electrode array patterns 2-A₁ to 2-A₆ as the electrode array patterns for the side electrodes disposed along the X-direction in order to detect a Y-axis coordinate. This figure also shows a case where four electrode array patterns 2-B₁ to 2-B₄ as the electrode array patterns for the center electrodes disposed in the Y-direction in order to detect an X-axis coordinate.

The respective electrode elements 201 may be disposed so as to be spaced and separated from each other and to have the distance between adjacent electrode elements minimized as seen in a plan view, depending on the shapes thereof, in order to obtain a desired precision required as a touch panel. For example, the respective electrode elements may be formed in a polygonal shape, such as a rectangular shape, a rhombus shape or a hexagonal shape, such that the electrode elements 201 disposed along the X-axis direction and the electrode elements 201 disposed along the Y-axis direction are closely disposed in the entire touch region and that the areas of the crossing regions where the electrode array patterns 2 along the respective axis directions cross each other are minimized as much as possible. The respective electrode elements may have a notch or a hole formed therein. By adopting such arrangement, it is possible to make the electrode elements unnoticeable to a user.

The transparent substrate 1 is formed of an electrically insulating substrate, which may be a glass substrate, a PET (polyethylene terephthalate) film or sheet, a PC (polycarbonate) film or sheet, for example.

The insulating film 3 is formed of a transparent and electrically insulating material, which may be an inorganic material, such as SiO₂, or an organic resin material, such as a photosensitive resin, for example. When SiO₂ in the former material is employed, it is easy to obtain a patterned insulating film by making use of a mask according to a sputtering method, although it is necessary to increase the length of a bridge wire since positional accuracy is low when depositing such an inorganic film by making use of a mask according to such a sputtering method. From this point of view, it is preferred that the electrically insulating film be a resin film disposed by employing a photosensitive resin material having a high positional accuracy. When the insulating film is disposed by employing a photosensitive resin, it is possible to easily obtain a patterned resin insulating film according to a photolithography process.

In particular, when the transparent substrate is a glass substrate, it is preferred to employ a photosensitive resin having a group reactive to a silanol group produced on the glass substrate. By employing such a photosensitive resin, it is possible to dispose an insulating film having a high adhesion because of chemical bond between the glass substrate and the photosensitive resin. Examples of the photosensitive resin include a photosensitive acrylic resin, a photosensitive methacrylic resin, a photosensitive polyimide-based resin, a photosensitive polysiloxane-based resin, a photosensitive polyvinyl alcohol resin and an acrylic urethane-based resin.

The bridge wires 4 are formed of a conductive substance, which is preferably made of a metal material capable of easily obtaining a high adhesion to the transparent substrate 1. In particular, when the transparent substrate is a glass substrate, it is preferred to employ a metal material, such as Mo, a Mo alloy, Al, an Al alloy, Au or an Au alloy, which has a high adhesion to a glass substrate, has a higher conductivity than ITO and is excellent in durability and abrasion resistance. An alloy having an increased corrosion resistance is preferably a Mo/Nb-based alloy or an Al/Nd-based alloy, for example. The bridge wires may be formed in a multilayer structure having, e.g. two layers or three layers. The bridge wires may be formed in a three layer structure of Mo-layer/Al-layer/Mo-layer, for example. When the bridge wires are made of such a metal material, it is possible to reduce the width, the length and the film thickness of the wires, thereby to increase the degree of freedom in design and to have a better appearance in comparison a case where ITO is employed.

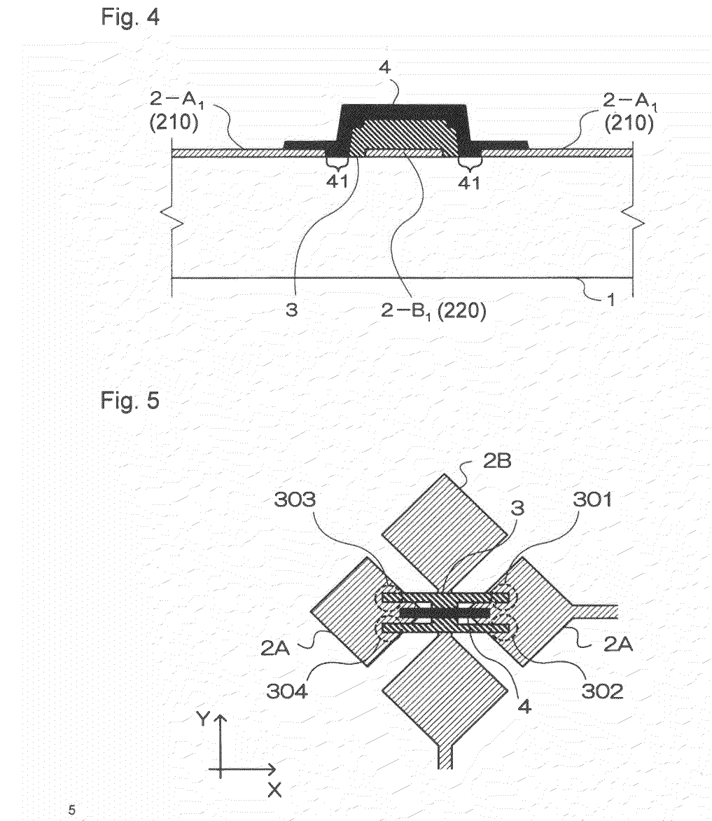

FIG. 4 is an enlarged schematic view showing a state where the transparent electrode pattern 2, the insulating film 3 and a bridge wire 4 are laminated. Please note that FIG. 4 is a cross-sectional view of the crossing region, taken along the X-axis direction, where the electrode array pattern 2-A₁ for the side electrodes and the electrode array pattern 2-B₁ for the center electrodes cross each other. In the case shown in FIG. 4, the transparent electrode pattern 2 is configured such that in the region where the electrode array pattern 2-A₁ and the electrode array pattern 2-B₁ cross each other, the electrode array pattern 2-A₁ is interrupted (is formed in a discontinuous shape) while the electrode array pattern 2-B₁ is not interrupted (is formed in a continuous shape). The insulating film 3 is disposed to cover a portion of the electrode array pattern 2-B₁ formed in a continuous shape, where the electrode array pattern 2-A₁ crosses (hereinbelow, referred to as the crossing portion, which corresponds to, e.g. a portion of the connection wire 202 in FIG. 2). The bridge wire 4 bridges the insulating film 3 to connect between the interrupted ends of the electrode array pattern 2-A₁ (for example, two aligned electrode elements 201 forming the electrode array pattern 2-A₁).

In this embodiment, the insulating film 3 is disposed so as to be out of contact with the two electrode elements to be connected by the bridge wire 4 (two electrodes 210 forming the electrode array pattern 2-A₁ for side electrodes in FIG. 4). Further, the bridge wire 4 is disposed so as to have an adhesion portion 41 for bringing the bridge wire into direct contact with the transparent substrate 1 between the insulation film 3 and each of the side electrodes 210 in such a state that the bridge wire 4 connects between the two side electrodes 210. Although each adhesion portion 41 is preferably disposed so as to extend over the entire gap region between the insulating film 3 and each of the side electrodes 210 as electrode elements in a longitudinal direction of the gap region (along the X-axis direction in this figure) in order to fix the bridge wire to the transparent electrodes more firmly, each adhesion portion may be disposed to extend by a certain portion of the length of the gap region, e.g. about half of the length of the gap region, in the longitudinal direction of the gap region. In FIG. 4, the electrode (the electrode forming the electrode array pattern 2-B₁ in FIG. 4) that is disposed between the two side electrodes 210 is a center electrode 220.

FIG. 5 is a schematic view showing another arrangement example of the transparent electrode pattern 2, the insulating film 3 and the bridge wire 4. In the case shown in FIG. 5, the transparent electrode pattern 2 has a single center electrode 2B and two side electrodes 2A formed therein such that the side electrodes are disposed so as to place the center electrode 2B therebetween. As shown in FIG. 5, it is sufficient that the insulating film 3 is disposed so as to be out of contact the respective side electrodes 2A in at least a region where the bridge wire 4 bridges. For example, the insulating film 3 may be disposed so as to be brought into contact the side electrodes 2A in regions (such as regions 301, 302, 303 and 304) other than the region where the bridge wire 4 is disposed or may be disposed so as to ride on the side electrodes 2A.

In the case shown in FIG. 5, the insulating film 3 has a narrow width in the X-axis direction in an overlapping region with the bridge wire 4, and the insulating film 3 is disposed so as to be out of contact with the side electrodes 2A in the overlapping region with the bridge wire 4. The insulating film 3 has a greater width in the X-axis direction in regions where the insulating film does not overlap the bridge wire 4, and the insulating film 3 is brought into contact with the side electrodes 2A in such regions 301 to 304. In this manner, portions of the insulating film 3 that do not overlap the bridge wire 4 may be brought into contact with the side electrodes.

Thus, it is possible to prevent the generation of deterioration of connection that the bridge wire 4 causes a connection failure because of peeling of the insulating film 3, since the insulating film 3 is configured so as not to ride on the respective side electrodes 210 as connection objects in at least the region where the bridge wire disposed. This arrangement makes use of the fact that in a case where the transparent substrate is a glass substrate, the resin film can have a stronger adhesive force to the transparent substrate 1 having an OH-group thereon when the adhesive force between the resin film (insulating film 3) and the transparent substrate 1 is compared to the adhesive force between the resin film (insulating film 3) and ITO. Thus, it is possible to prevent the generation of deterioration of connection that the bridge wire 4 causes a connection failure because of peeling of the insulating film 3. By selecting a proper metal material to form the bridge wire 4, it is possible to further increase the adhesive force of the bridge wire 4 to the transparent substrate 1 in comparison with a case where the bridge wire is formed of a film of metal oxide, such as ITO. As described above, it is possible to connect between the bridge wire 4 and each of the transparent electrodes more firmly by making use of not only the adhesive force between the insulating film 3 and the transparent substrate 1 but also the adhesive force between the bridge wire 4 and the transparent substrate 1 in the gap region between the insulating film 3 and each of the electrode elements forming side electrodes.

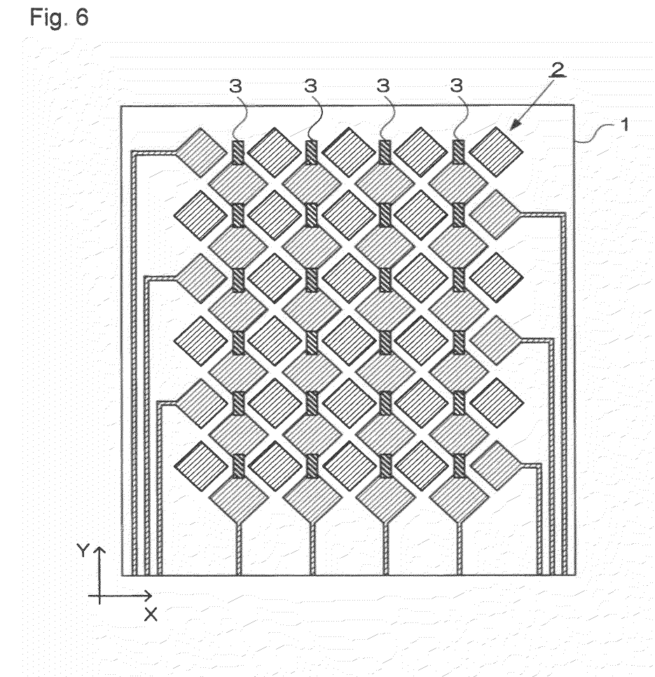

Now, a typical example of the method for producing the touch panel 10 according to this embodiment will be described. First, the transparent electrode pattern 2 is disposed on the single side of the transparent substrate 1. For example, an ITO film is deposited on the single side of the transparent substrate 1 by, e.g. a sputtering method, and the deposited ITO film is patterned, as shown in FIG. 3, by making use of a photolithographic technique to process the transparent electrode pattern 2 in a desired pattern. Next, the insulating film 3 is disposed so as to cover specific portions of the transparent electrode pattern 2 (the regions where the electrode array patterns for the side electrodes along the X-axis direction cross the electrode array patterns for the center electrodes along the Y-axis direction, i.e. crossing regions in the electrode array patterns) on the same side of the transparent substrate 1 with the transparent electrode pattern 2 disposed thereon (the side with the transparent electrode pattern 2 disposed thereon). The insulating film 3 may be patterned by a photolithography process where a photosensitive resin is applied to the insulating film and is exposed with a mask having a certain pattern used, and the insulating film is etched. At that time, the insulating film is disposed to prevent both edges thereof in each of the crossing regions from extending to the side electrodes, with the result that gap regions are formed to prevent both edges from having contact with the side electrodes. FIG. 6 is a schematic view showing a typical example of a touch panel 10 in a state where the insulating film 3 is disposed in each of the crossing regions.

Next, the bridge wire 4 is disposed to connect between opposed interrupted edges of the transparent electrode pattern 2 (edges of the electrode elements formed by interrupting each of the electrode array patterns 2 for the side electrodes) so as to bridge the insulating film 3 disposed in each of the crossing regions. For example, the bridge wire 4 may be disposed by employing, e.g. a sputtering method to deposit a conductive metallic substance as a metal film on the same side of the transparent substrate 1 with the insulating film 3 disposed thereon (the side with the insulating film 3 disposed thereon), and patterning the metal film in a certain pattern by a photolithography process. In this way, the state shown in FIG. 1 is produced.

When the resistance of the circuitous wires for each of the electrode array patterns is required to be reduced, the metal film may be disposed so as to cover the circuitous wires as well when in the process for disposing the bridge wires, e.g. a sputtering method is employed to dispose the metal film on the same side of the transparent substrate with the insulating film. Then the metal film may be also patterned to form, on each of the circuitous wires, a metal film having a low resistance at the same time when the metal film is patterned to form the bridge wires by the photolithography method.

When the circuitous wires for each of the electrode array patterns are not disposed in advance, the metal film may be disposed so as to cover planned positions for the circuitous wires as well when in the process for disposing the bridge wires, e.g. a sputtering method is employed to dispose the metal film on the same side of the transparent substrate with the insulating film. Then the metal film may be also patterned to form the circuitous wires at the same time when the metal film is patterned to form the bridge wires by the photolithography method.

Although FIG. 1 shows a case where the transparent electrode pattern 2 is first disposed, followed by disposing the insulating film 3 and disposing the bridge wires 4, the order of the processes may be reversed. In other words, the respective bridge wires 4 may be first disposed on respective desired crossing regions, followed by disposing the insulating film 3 so as not only to cover intermediate portions of the respective bridge wires 4 (containing at least regions where the crossing regions of the transparent electrode pattern 2 are expected to be disposed) but also to expose opposed edges of the respective bridge wires, and disposing the transparent electrode pattern 2 such that the opposed edges of the respective bridge wires 4 are connected to two relevant electrode elements as connection objects to place the two relevant electrode elements in electrical connection. In the latter order of the processes as well, the insulating film 3 is disposed so as to be out of contact with the two relevant electrode elements as the connection objects of each of the bridge wires 4 covered by the insulating film 3. It should be noted that in this embodiment, wires that are disposed to sandwich the insulating film 3 along with the respective transparent electrodes forming the electrode array patterns extending along one of the axis directions in the respective crossing regions while connecting the interrupted opposed transparent electrodes forming the electrode array patterns are referred to the bridge wires 4 irrespectively of whether the wires are disposed so as to bridge or to pass under the insulating film 3.

Although FIGS. 1 to 6 show cases where the respective electrode array patterns 2 for the side electrodes and for the center electrodes in a crossing form are disposed such that the electrode array patterns extending along one of the axis directions are formed in an interrupted fashion while the electrode array patterns extending along the other axis direction are formed in a continuous fashion, it is sufficient that the electrode pattern with the connection structure between electrodes according to the present invention applied thereto includes an arrangement of three independent electrodes in each of the crossing regions. The arrangement of each of the electrode array patterns in a touch panel is not limited to the case shown in FIG. 3. For example, the electrode array patterns extending along the same axis direction may be patterned such that an electrode array pattern is formed in a continuous fashion while another electrode array pattern is formed in an interrupted fashion. Instead, for example, a single electrode array pattern is patterned such that some of adjacent electrode elements are formed in a continuous fashion while the remaining adjacent electrode elements are formed in an interrupted fashion.

The touch panel 10 includes a circuit unit to monitor capacitance through the respective electrode array patterns in the transparent electrode pattern 2, although not shown in the accompanying drawings. The circuit unit may be connected to the terminals of the circuitous wires 203 of the respective electrode array patterns through, e.g. a flexible film. The circuit unit may be configured by mounting an IC chip directly on a flexible film connected to the terminals of the circuitous wires 203 of the respective electrode array patterns.

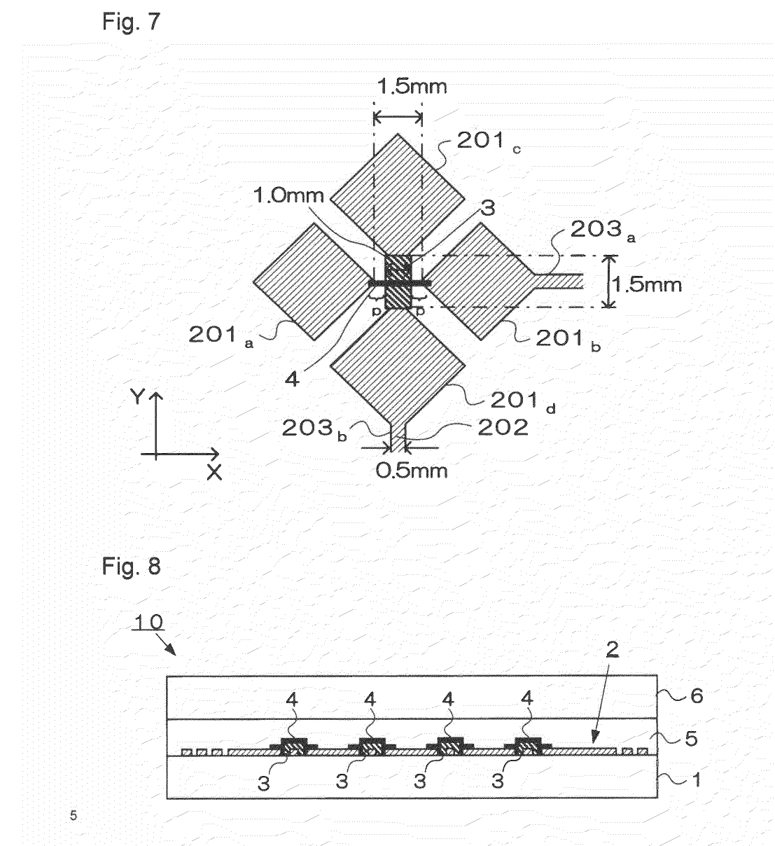

For example, as shown in FIG. 8, the touch panel 10 may include a protection glass layer 6, which is laminated through an adhesion film 5 made of, e.g. a UV-curable resin on the arrayed electrodes disposed on the transparent substrate 1 (specifically, the arrayed electrodes formed of the transparent electrode pattern 2 and the bridge wire 4 laminated with the insulating film 3 sandwiched therebetween and extending in the X-axis direction and the Y-axis direction, respectively). FIG. 8 is a schematic cross-sectional view showing an arrangement example of the touch panel 10 different from FIG. 6. In this case, it is possible to detect from the side of the protective glass layer 6 where a touch is made.

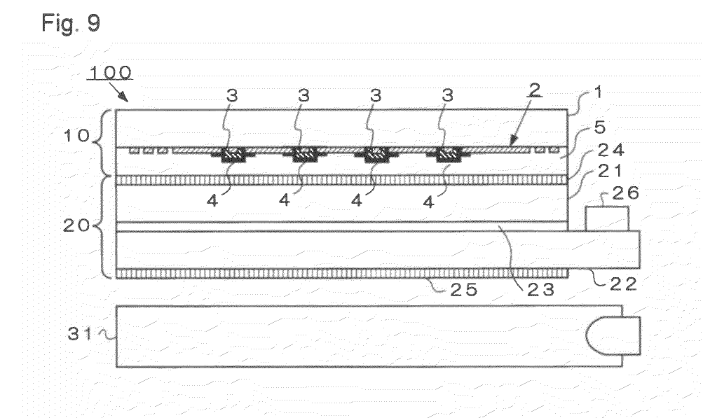

For example, as shown in FIG. 9, the touch panel 10 may be incorporated into a display device, such as a liquid crystal display device, being configured as a display device having a function of serving as a capacitive touch panel capable of detecting where a touch is made. FIG. 9 is a schematic cross-section view showing one arrangement example of the display device having a function of serving as a capacitive touch panel. The display device having a function of serving as a capacitive touch panel 100 shown in FIG. 9 includes a touch panel forming portion 10, a display panel forming portion 20 and a backlight 31.

The touch panel forming portion 10 may be configured in the same way as the touch panel 10 as shown in FIG. 1. In other words, it is sufficient that arrayed electrodes that function as transparent electrodes arrayed in a matrix form in a transparent electrode pattern (more specifically, arrayed electrodes formed of the transparent electrode pattern 2 and the bridge wires 4 laminated with the insulating film 3 sandwiched therebetween and aligned along the X-axis direction and the Y-axis direction, respectively) are disposed on a single side of the transparent substrate 1.

The display panel forming portion 20 may be configured in the same way as a general display device. For example, when the display device is a liquid crystal display device, the display panel forming portion may be configured so as to sandwich a liquid crystal layer 23 between a first transparent substrate 21 and a second transparent substrate 22. Reference numerals 24 and 25 designate polarizing plates. Reference numeral 26 designates a driving IC. Although the respective transparent substrates 21 and 22 have segment electrodes, common electrodes and the like formed thereon to control the liquid crystal state, these electrodes are not shown in this figure. Although the liquid crystal layer 23 is sealed by the respective transparent substrates 21 and 22, and a sealing member, the sealing member is not shown in this figure.

For example, the arrayed electrodes disposed on the transparent substrate 1 of the touch panel forming portion 10, and a viewer side top layer (the polarizing plate 24 in this figure) of the display panel forming portion 20 are superimposed through an adhesive layer 5 made of, e.g. a UV-curable resin to configure a single liquid crystal display device. FIG. 9 shows a case where a side of the transparent substrate 1 with the arrayed electrodes disposed thereon so as to form the touch panel faces the liquid crystal display device. The touch panel can be easily incorporated into a display device without increasing the number of parts, such as a protective glass layer, since the arrayed electrodes for detecting where a touch is made are disposed on only a single side of the transparent substrate 1 as described above. It is possible to make a user readily understand where a touch should be made on the touch panel by cooperating with such a display device to, e.g. modify display according to how to touch the touch panel.

If superimposing of the touch panel and a liquid crystal display device produces noise in a change in capacitance detected from the respective electrode array patterns disposed on the transparent substrate 1 of the touch panel forming portion 10, a transparent electrode may be disposed between the touch panel forming portion 10 and the display panel forming portion 20 to function as grounding. The transparent electrode that is disposed between the touch panel forming portion 10 and the display panel forming portion 20 may be disposed so as to cover the entire panel region without being patterned.

It is sufficient that the transparent electrode that functions as grounding is disposed on an opposite side of the side of the touch panel forming portion 10 with a touch being made thereon as seen from the arrayed electrodes disposed on the transparent substrate 1. For example, the touch panel forming portion 10 may be configured to have a protective glass layer 6 laminated, through an adhesive layer 5 made of, e.g. a resin, on the arrayed electrodes disposed on a transparent substrate 1 as shown in FIG. 8 and to dispose a transparent substrate made of, e.g. ITO on the entire surface of the transparent substrate facing the top layer of a liquid crystal display panel forming portion 20 and be superimposed on the liquid crystal display panel forming portion through an adhesive layer 5 made of, e.g. a UV-curable resin. By adopting this arrangement, it is possible to stably detect where a touch is made, without being affected by any noise from the display device.

Although explanation has been made about a case where a UV-curable resin or the like is employed to laminate a display device or a protective glass layer (protective cover) or the like on the transparent substrate 1 with the arrayed electrodes disposed to detect where a touch is made, a double-sided adhesive (or PSA) film may be employed as another method. When a PSA film or the like is employed, such a PSA film or the like may be bonded to the arrayed electrodes, followed by superimposing the transparent substrate along with a liquid crystal display device or a protective cover in a vacuum, for example. After that, it is preferred to employ an autoclave system (pressurizing and degassing system) to subject the superimposed complex to degassing and pressurizing treatment. When a resin is employed, a liquid resin may be applied to the arrayed electrodes on the transparent substrate, followed by slowly laminating a liquid crystal display device or a protective cover on the substrate with the resin applied thereto and finally carrying out a UV-exposure treatment to cure the resin.

### EXAMPLE 1

This example is a case where a touch panel has four electrode-array patterns for center electrodes and six electrode-array patterns for side electrodes in a matrix form in order to obtain a touch region having a width of 4 cm and a length of 6 cm. In this example, an ITO film was deposited so as to have a film thickness of 20 nm on a single side of a glass substrate having a thickness of 0.55 mm by a sputtering method and was patterned to form the respective electrode patterns 2 as shown in FIG. 3 by employing a photolithography technique. Specifically, the electrode elements 201 forming the respective electrode array patterns were set in a rhombus shape, and a transparent electrode pattern 2 was formed so as to include the six electrode-array patterns for the side electrodes 2-A₁ to 2-A₆ formed of groups of electrode elements aligned along the X-axis direction as a transverse direction, the four electrode-array patterns for the center electrodes 2-B₁ to 2-B₄ formed of groups of electrode elements aligned along the Y-axis direction as a longitudinal direction, and circuitous wires leading thereto. In this example, among the respective electrode array patterns, the electrode array patterns 2-B₁ to 2-B₄ for the center electrodes formed of aligned electrode sets along the Y-axis direction were formed in a continuous shape by disposing connection wires 202 connecting adjacent electrode elements, and the electrode array patterns 2-A₁ to 2-A₆ for the side electrodes were formed in a discontinuous shape to separate adjacent electrode elements without disposing connection wires 202. In this example, one electrode element 201 having a rhombus shape had one side set at a length of 5 mm, and each connection wire 202 had a width and a length set at 0.5 mm and 1.5 mm, respectively.

Next, an acrylic resin-based photosensitive resin was applied to cover the above-mentioned transparent electrode pattern. By employing a photolithography technique using an exposure mask having a certain pattern, the photosensitive resin film was patterned to form an electrically insulating film made of a resin material, which bridged the electrode array patterns for the side electrodes formed in a continuous shape in crossing regions where the electrode array patterns 2-A₁ to 2-A₆ for the side electrodes cross the electrode array patterns 2-B₁ to 2-B₄ for the center electrodes, and which form gap regions in the respective crossing regions by being disposed so as to be out of contact with the opposed electrode elements of the respective electrode array patterns 2-A₁ to 2-A₆ for the side electrodes in the respective crossing regions. By adopting this arrangement, the insulting film is configured such that both opposed edges are out of contact with opposed side electrodes in each of the crossing regions. The insulating film had a length set at 1.0 mm along the X-axis direction and a width set at 1.0 mm in the Y-axis direction in each of the crossing regions.

Next, a conductive metal film was deposited to cover the above-mentioned transparent electrode pattern and the insulating film so as to have a film thickness of 350 nm by a sputtering method, and the deposited metal film was patterned to form bridge wires by employing a photolithographic technique using an exposure mask having a certain pattern. In this example, the metal film was configured in a structure having three metal layers, which were formed of a Mo layer containing Nb, an Al layer containing Nd and a Mo layer containing Nb in this order from the glass substrate side. The bridge wires had a length along the X-axis direction, a width and a film thickness set at 5.0 mm, 0.1 mm and 20 μm, respectively.

Thus, as shown in FIG. 7, the resin insulating film 3 was disposed so as to bridge the connection wire 202 between adjacent electrode elements 201c and 201d of the electrode array patterns for the center electrodes, and to form gap regions p between each of the connection wires 202 and each of adjacent electrode elements 201a and 201b positioned on both sides of each of the connection wires and forming the electrodes array patterns for the side electrodes. Further, the bridge wires 4 were disposed to bridge the insulating film 3 so as to connect between adjacent electrode elements 201a and 201b of the electrode array patterns for the side electrodes. In this example, the bridge wires 4 were brought into direct contact with the surface of the transparent substrate in the gap regions p.

Then, a circuit substrate was connected through a flexible film to the terminals of the circuitous wires 203, which were disposed on the transparent substrate 1 to lead to the respective electrode array patterns. It was confirmed that the touch panel 10 thus completed was employed to be capable of detecting where a finger touch was made. Further, it was confirmed that even if a protective glass film 6 was laminated through a resin adhesive film 5 on the touch panel 10 thus completed, it was possible to detect where a finger touch was made.

The present invention is appropriately applicable to not only a case where transparent electrodes are connected on a transparent substrate forming a touch panel for employing a matrix system to detect where a touch is made but also to a case where two electrodes are connected so as to bridge another electrode on a substrate without placing the latter electrode in electrical connection.

Obviously, numerous modifications and variations of the present invention are possible in light of the above teachings. It is therefore to be understood that within the scope of the appended claims, the invention may be practiced otherwise than as specifically described herein.

The entire disclosure of Japanese Patent Application No. 2009-121354 filed on May 19, 2009 including specification, claims, drawings and summary is incorporated herein by reference in its entirety.

What is claimed is:

1. A connection structure between electrodes, comprising:
a center electrode disposed as a transparent electrode on a transparent substrate;
paired side electrodes disposed as transparent electrodes on the transparent substrate so as to place the center electrode therebetween;
a bridge wire serving as a wire to connect between the paired side electrodes; and
an electrically insulating film disposed between the center electrode and the bridge wire;
wherein the bridge wire comprises a metal material;
the electrically insulating film is disposed so as to be out of contact with the side electrodes at least within a certain range; and
the bridge wire is disposed so as to be brought into direct contact with the transparent substrate in a gap region, the gap region being formed by disposing the electrically insulating film so as to be out of contact with the side electrodes.

2. The connection structure between electrodes according to claim 1, wherein the electrically insulating film is disposed so as to be out of contact with the side electrodes at least within a region where the bridge wire is disposed.

3. A connection structure between electrodes, comprising:
a center electrode disposed as a transparent electrode on a transparent substrate;
paired side electrodes disposed as transparent electrodes on the transparent substrate so as to place the center electrode therebetween;
a bridge wire serving as a wire to connect between the paired side electrodes; and
an electrically insulating film disposed between the center electrode and the bridge wire;
wherein the bridge wire comprises a metal material; and
the bridge wire is first disposed on a crossing region, followed by disposing the electrically insulating film and disposing the paired side electrodes;
the electrically insulating film disposed so as not only to cover intermediate portion of the bridge wire but also to expose opposed edges of the bridge wire, and the opposed edges of the bridge wire are connected to the paired side electrodes; and
the electrically insulating film is disposed so as to be out of contact with the paired side electrodes.

4. A connection structure between electrodes, comprising:
a center electrode disposed as a transparent electrode on a transparent substrate;
paired side electrodes disposed as transparent electrodes on the transparent substrate so as to place the center electrode therebetween;
an electrically insulating film disposed so as to bridge a portion of the center electrode; and
a bridge wire bridging the electrically insulating film to serve as a wire to connect between the paired side electrodes;
wherein the bridge wire comprises a metal material; and
the electrically insulating film disposed so as to bridge the portion of the center electrode has both edges extending so as to be out of contact the paired side electrodes and forming a gap region so as to prevent both edges from being brought into contact with the side electrodes, and the bridge wire is brought into direct contact with the transparent substrate in the gap region.

5. The connection structure between electrodes according to claim 1, wherein the electrically insulating film comprises a resin material.

6. The connection structure between electrodes according to claim 3, wherein the electrically insulating film comprises a resin material.

7. The connection structure between electrodes according to claim 4, wherein the electrically insulating film comprises a resin material.

8. A touch panel comprising a center electrode disposed as a transparent electrode on a transparent substrate; and paired side electrodes disposed on the transparent substrate so as to place the center electrode therebetween, the paired side electrodes being connected together without being brought into electrical contact with the center electrode such that electrode arrays cross on a single side of the transparent substrate;
the touch panel further comprising:
a bridge wire serving as a wire to connect between the paired side electrodes; and
an electrically insulating film disposed between the center electrode and the bridge wire;
wherein the bridge wire comprises a metal material;
the electrically insulating film is disposed so as to be out of contact with the side electrode at least within a certain range; and
the bridge wire is disposed so as to be brought into direct contact with the transparent substrate in a gap region, the gap region being formed by disposing the electrically insulating film so as to be out of contact with the side electrode.

9. The touch panel according to claim 8, wherein the electrically insulating film is disposed so as to be out of contact with the side electrode at least within a region where the bridge wire is disposed.

10. A touch panel comprising a center electrode disposed as a transparent electrode on a transparent substrate; and paired side electrodes disposed as transparent electrodes on the transparent substrate so as to place the center electrode therebetween, the paired side electrodes being connected together without being brought into electrical contact with the center electrode such that electrode arrays cross on a single side of the transparent substrate;
the touch panel further comprising:
a bridge wire serving as a wire to connect between the paired side electrodes; and
an electrically insulating film disposed between the center electrode and the bridge wire;
wherein the bridge wire comprises a metal material; and
the bridge wire is first disposed on a crossing region, followed by disposing the electrically insulating film and disposing the paired side electrodes;
the electrically insulating film disposed so as not only to cover intermediate portion of the bridge wire but also to expose opposed edges of the bridge wire, and the opposed edges of the bridge wire are connected to the paired side electrodes; and
the electrically insulating film is disposed so as to be out of contact with the paired side electrodes.

11. A touch panel comprising a center electrode disposed as a transparent electrode on a transparent substrate; and paired side electrodes disposed as transparent electrodes on the transparent substrate so as to place the center electrode therebetween, the paired side electrodes being connected together without being brought into electrical contact with the center electrode such that electrode arrays cross on a single side of the transparent substrate;
the touch panel further comprising:
an electrically insulating film disposed so as to bridge a portion of the center electrode; and
a bridge wire bridging the electrically insulating film to serve as a wire to connect between the paired side electrodes;
wherein the bridge wire comprises a metal material; and
the electrically insulating film disposed so as to bridge the portion of the center electrode has both edges extending so as to be out of contact the paired side electrodes and forming a gap region to prevent both edges from being brought into contact with the side electrodes, and the bridge wire is brought into direct contact with the transparent substrate in the gap region.

12. The touch panel according to claim 8, wherein the electrically insulating film comprises a resin material.

13. The touch panel according to claim 10, wherein the electrically insulating film comprises a resin material.

14. The touch panel according to claim 11, wherein the electrically insulating film comprises a resin material.
